(19) United States
(12) Patent Application Publication
(10) Pub. No.: US 2021/0223637 A1
(43) Pub. Date: Jul. 22, 2021

(54) LIGHT VALVE TYPE MASK

(71) Applicant: WUHAN CHINA STAR OPTOELECTRONICS SEMICONDUCTOR DISPLAY TECHNOLOGY CO., LTD., Wuhan, Hubei (CN)

(72) Inventors: Junying MU, Wuhan, Hubei (CN); Sangyeob LEE, Wuhan, Hubei (CN)

(21) Appl. No.: 16/308,870

(22) PCT Filed: Nov. 1, 2018
(86) PCT No.: PCT/CN2018/113252

§ 371 Date: Dec. 11, 2018

(30) Foreign Application Priority Data
Sep. 20, 2018 (CN) 201811100602.9

(51) Int. Cl. G02F 1/1343; G02F 1/1335; G03F 1/38

(52) U.S. Cl. CPC G02F 1/134309; G03F 1/38; G02F 1/13439; G02F 1/133528

(57) ABSTRACT

A light valve type mask is provided. The light valve type mask includes a first substrate, a second substrate, a first electrode, a second electrode, and a light valve medium. The first electrode is disposed on a lower surface of the first substrate. The first electrode includes at least one first sub-electrode having transmissivity, at least one second sub-electrode having transmissivity, and at least one third sub-electrode having no transmissivity. The second electrode is disposed on an upper surface of the second substrate. The light valve medium is disposed between the first electrode and the second electrode.

### FIELD OF INVENTION

The present disclosure relates to the field of mask exposure technologies, and more particularly to a light valve type mask.

### BACKGROUND OF INVENTION

Current masks for lithography technologies have a fixed opening area (sub-pixels) distributions and resolutions, and multiple sets of masks are required for products with different designs and different resolutions. Therefore, large numbers of current masks are used, where pixel size cannot be adjusted, and resolutions cannot be controlled.

Therefore, there is a need to provide a light valve type mask to solve technical problems of the prior art, to adjust pixel size, to control resolutions, and to be suitable for various electronic products having different pixel designs.

### SUMMARY OF INVENTION

In order to solve the above technical problems, an embodiment of the present disclosure provides a light valve type mask. The light valve type mask includes a first substrate, a second substrate, a first electrode, a second electrode, and a light valve medium. The second substrate is disposed opposite to the first substrate. The first electrode is disposed on a lower surface of the first substrate. The first electrode includes at least one first sub-electrode having transmissivity, at least one second sub-electrode having transmissivity, and at least one third sub-electrode having no transmissivity. The second electrode is disposed on an upper surface of the second substrate and disposed opposite to the first electrode. The light valve medium is disposed between the first electrode and the second electrode. The at least one third sub-electrode is disposed between the at least one first sub-electrode and the at least one second sub-electrode. A first pixel area formed by the at least one first sub-electrode is different from a second pixel area formed by the at least one second sub-electrode. A size of the at least one first sub-electrode, a size of the at least one second sub-electrode, and a size of the at least one third sub-electrode are same. A number of the at least one first sub-electrode, a number of the at least one second sub-electrode, and a number of the at least one third sub-electrode are different.

In an embodiment of the present disclosure, a voltage is applied to the at least one first sub-electrode and the at least one second sub-electrode to make the at least one first sub-electrode and the at least one second sub-electrode transmissive, and no voltage is applied to the at least one third sub-electrode to make the at least one third sub-electrode non-transmissive.

In an embodiment of the present disclosure, the first pixel area formed by the at least one first sub-electrode is greater than the second pixel area formed by the at least one second sub-electrode.

In an embodiment of the present disclosure, the first pixel area formed by the at least one first sub-electrode is twice the second pixel area formed by the at least one second sub-electrode.

In an embodiment of the present disclosure, the number of the at least one first sub-electrode is one, the number of the at least one second sub-electrode is two, and the number of the at least one third sub-electrode is seven.

In an embodiment of the present disclosure, the second electrode is a common electrode.

In an embodiment of the present disclosure, the light valve type mask further includes a first polarizing device and a second polarizing device, the first polarizing device is disposed on an upper surface of the first substrate, and the second polarizing device is disposed on a lower surface of the second substrate.

According to an embodiment of the present disclosure, a light valve type mask includes a first substrate, a second substrate, a first electrode, a second electrode, and a light valve medium. The second substrate is disposed opposite to the first substrate. The first electrode is disposed on a lower surface of the first substrate. The first electrode includes at least one first sub-electrode having transmissivity, at least one second sub-electrode having transmissivity, and at least one third sub-electrode having no transmissivity. The second electrode is disposed on an upper surface of the second substrate and disposed opposite to the first electrode. The light valve medium is disposed between the first electrode and the second electrode.

In an embodiment of the present disclosure, a voltage is applied to the at least one first sub-electrode and the at least one second sub-electrode to make the at least one first sub-electrode and the at least one second sub-electrode transmissive, and no voltage is applied to the at least one third sub-electrode to make the at least one third sub-electrode non-transmissive.

In an embodiment of the present disclosure, the at least one third sub-electrode is disposed between the at least one first sub-electrode and the at least one second sub-electrode.

In an embodiment of the present disclosure, a first pixel area formed by the at least one first sub-electrode is different from a second pixel area formed by the at least one second sub-electrode.

In an embodiment of the present disclosure, the first pixel area formed by the at least one first sub-electrode is greater than the second pixel area formed by the at least one second sub-electrode.

In an embodiment of the present disclosure, the first pixel area formed by the at least one first sub-electrode is twice the second pixel area formed by the at least one second sub-electrode.

In an embodiment of the present disclosure, a size of the at least one first sub-electrode, a size of the at least one second sub-electrode, and a size of the at least one third sub-electrode are same.

In an embodiment of the present disclosure, the number of the at least one first sub-electrode is one, the number of the at least one second sub-electrode is two, and the number of the at least one third sub-electrode is seven.

In an embodiment of the present disclosure, the second electrode is a common electrode.

In an embodiment of the present disclosure, the light valve type mask further includes a first polarizing device and a second polarizing device, the first polarizing device is disposed on an upper surface of the first substrate, and the second polarizing device is disposed on a lower surface of the second substrate.

Compared with the prior art, in order to solve the above technical problems, the light valve type mask in the embodiment of the present disclosure can adjust pixel size, control resolutions, and be suitable for various electronic products having different pixel designs by at least one first sub-electrode having transmissivity, at least one second sub-electrode having transmissivity, and at least one third sub-electrode having no transmissivity.

### DESCRIPTION OF DRAWINGS

FIG. 1 is a schematic structural view of a light valve type mask according to an embodiment of the present disclosure.

FIG. 2 is a schematic structural view of a light valve type mask according to an embodiment of the present disclosure.

### DETAILED DESCRIPTION OF PREFERRED EMBODIMENTS

The following description of the various embodiments is provided to illustrate the specific embodiments.

The above and other objects, features, and advantages of the present disclosure will becomes better understood with reference to the following detailed description considered in connection with the accompanying drawings. Furthermore, directional terms described by the present disclosure, such as up, down, top, bottom, front, back, left, right, inner, outer, side, surrounding, center, horizontal, vertical, longitudinal, axial, radial, uppermost or lowermost, etc., are only directions by referring to the accompanying drawings, and thus the used terms are used only for the purpose of describing embodiments of the present disclosure and are not intended to be limiting of the present disclosure.

In the drawings, units with similar structures are labeled with the same reference number.

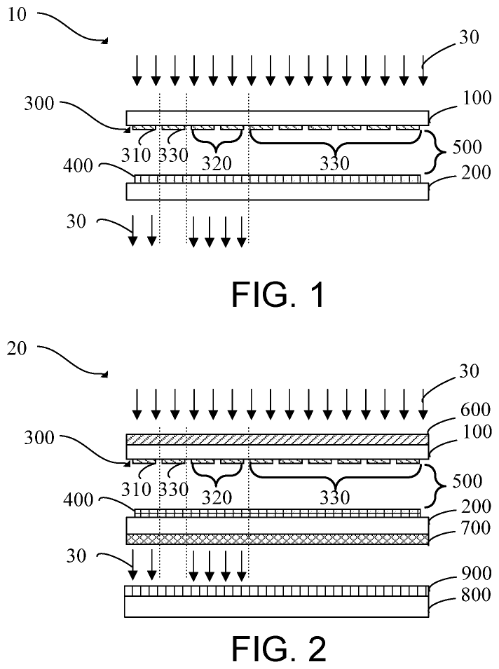

Refer to FIG. 1, a schematic structural view of a light valve type mask according to an embodiment of the present disclosure is provided. In an embodiment of the present disclosure, a light valve type mask 10 includes a first substrate 100, a second substrate 200, a first electrode 300, a second electrode 400, and a light valve medium 500. The second substrate 200 is disposed opposite to the first substrate 100. The first electrode 300 is disposed on a lower surface of the first substrate 100. The first electrode 300 includes at least one first sub-electrode 310 having transmissivity, at least one second sub-electrode 320 having transmissivity, and at least one third sub-electrode 330 having no transmissivity. The second electrode 400 is disposed on an upper surface of the second substrate 200 and disposed opposite to the first electrode 300. The light valve medium 500 is disposed between the first electrode 300 and the second electrode 400. The light valve type mask 10 in the embodiment of the present disclosure can adjust pixel size, control resolutions, and be suitable for various electronic products having different pixel designs by at least one first sub-electrode 310 having transmissivity, at least one second sub-electrode 320 having transmissivity, and at least one third sub-electrode 330 having no transmissivity.

In details, an electric field is applied between the first electrode 300 and the second electrode 400, such that the light valve medium 500 of a corresponding area changes a polarization direction of incident light 30, and the incident light 30 selectively passes through the light valve medium 500. The light valve medium 500 is, for example, liquid crystal. The second electrode 400 is, for example, a common electrode.

In details, a voltage may be selectively applied between the at least one first sub-electrode 310, the at least one second sub-electrode 320, and the at least one third sub-electrode 330, for example, a voltage is applied to the at least one first sub-electrode 310 and the at least one second sub-electrode 320 to make the at least one first sub-electrode 310 and the at least one second sub-electrode 320 transmissive, and no voltage is applied to the at least one third sub-electrode 330 to make the at least one third sub-electrode 330 non-transmissive. The at least one third sub-electrode 330 is, for example, disposed between the at least one first sub-electrode 310 and the at least one second sub-electrode 320. Therefore, resolutions can be controlled by controlling an area where the voltage is applied.

In an embodiment of the present disclosure, the number of the at least one first sub-electrode 310 is one, the number of the at least one second sub-electrode 320 is two, and the number of the at least one third sub-electrode 330 is seven.

In an embodiment of the present disclosure, a first pixel area formed by the at least one first sub-electrode 310 is different from a second pixel area formed by the at least one second sub-electrode 320. The first pixel area formed by the at least one first sub-electrode 310 is, for example, greater than the second pixel area formed by the at least one second sub-electrode 320. In details, the first pixel area formed by the at least one first sub-electrode 310 is twice the second pixel area formed by the at least one second sub-electrode 320. A size of the at least one first sub-electrode 310, a size of the at least one second sub-electrode 320, and a size of the at least one third sub-electrode 330 are same. For example, sizes of the at least one first sub-electrode 310, the at least one second sub-electrode 320, and the at least one third sub-electrode 330 are 5 um in length and width.

Refer to FIG. 2, a schematic structural view of a light valve type mask according to an embodiment of the present disclosure is provided. The structure and operation of the light valve type mask 20 of the embodiment of the present disclosure are similar to those of the light valve type mask 10 of FIG. 1, a main difference is that the light valve type mask 20 of the embodiment of the present disclosure further includes a first polarizing device 600 and a second polarizing device 700. The first polarizing device 600 is disposed on an upper surface of the first substrate 100, and the second polarizing device 700 is disposed on a lower surface of the second substrate 200.

In details, an electric field is applied between the first electrode 300 and the second electrode 400, such that the light valve medium 500 of a corresponding area changes a polarization direction of incident light 30, and the incident light 30 selectively passes through the light valve medium 500. The first polarizing device 600 and the second polarizing device 700 cooperate to increase utilization of the incident light 30 by the light valve type mask.

In addition, the light valve type mask 20 of the embodiment of the present disclosure further includes a third substrate 800 and a film 900. The film 900 is disposed on the third substrate 800. The incident light 30 passes through the at least one first sub-electrode 310 and the at least one second sub-electrode 320 to reach the film 900 on the third substrate 800 or a surface of the third substrate 800. The light valve type mask 20 of the embodiment of the present disclosure also drives a circuit (not shown in the drawings) for controlling the voltages of the first electrode 300 and the second electrode 400 to control strength of the incident light 30 passing through the light valve type mask 10.

In summary, the light valve type mask in the embodiment of the present disclosure can adjust pixel size, control resolutions, and be suitable for various electronic products having different pixel designs by at least one first sub-electrode having transmissivity, at least one second sub-electrode having transmissivity, and at least one third sub-electrode having no transmissivity. The light valve type mask in the embodiment of the present disclosure can control resolutions by controlling an area where the voltage is applied, can be applied in the field of micro masks, and a number of used masks is greatly reduced compared to conventional coated masks.

Although the present disclosure is described via one or more embodiments, those of ordinary skill in the art can come up with equivalent variations and modifications based upon the understanding of the specification and the accompanying drawings. The present disclosure includes all such modifications and variations and is only limited by the scope of the appended claims. In particular, as to the various functions performed by the components described above, the terms used to describe the components are intended to correspond to any component performing the specific functions (e.g., which are functionally equivalent) of the components (unless otherwise indicated), even those which are structurally different from the disclosed structure for performing the functions in the exemplary embodiments in the specification shown herein. In addition, although a particular feature in the specification is disclosed in only one of many embodiments, this feature may be combined with one or more features in other embodiments which are desirable and advantageous to a given or particular application. Moreover, the terms “include”, “have”, “consist of”, or variations thereof used in the detailed description or the claims are intended to be used in a manner similar to the term “comprising”.

In summary, although the preferable embodiments of the present disclosure have been disclosed above. It should be noted that those of ordinary skill in the art can make a variety of improvements and substitutions on the premise of not deviating from the technical principle of the present disclosure, and these improvements and substitutions should be encompassed within the protection scope of the present disclosure.

1. A light valve type mask, comprising:
a first substrate;
a second substrate disposed opposite to the first substrate;
a first electrode disposed on a lower surface of the first substrate, the first electrode comprising at least one first sub-electrode having transmissivity, at least one second sub-electrode having transmissivity, and at least one third sub-electrode having no transmissivity;
a second electrode disposed on an upper surface of the second substrate and disposed opposite to the first electrode; and
a light valve medium disposed between the first electrode and the second electrode;
wherein the at least one third sub-electrode is disposed between the at least one first sub-electrode and the at least one second sub-electrode;
wherein a first pixel area formed by the at least one first sub-electrode is different from a second pixel area formed by the at least one second sub-electrode;
wherein a size of the at least one first sub-electrode, a size of the at least one second sub-electrode, and a size of the at least one third sub-electrode are same;
wherein a number of the at least one first sub-electrode, a number of the at least one second sub-electrode, and a number of the at least one third sub-electrode are different.

2. The light valve type mask according to claim 1, wherein a voltage is applied to the at least one first sub-electrode and the at least one second sub-electrode to make the at least one first sub-electrode and the at least one second sub-electrode transmissive, and no voltage is applied to the at least one third sub-electrode to make the at least one third sub-electrode non-transmissive.

3. The light valve type mask according to claim 1, wherein the first pixel area formed by the at least one first sub-electrode is greater than the second pixel area formed by the at least one second sub-electrode.

4. The light valve type mask according to claim 3, wherein the first pixel area formed by the at least one first sub-electrode is twice the second pixel area formed by the at least one second sub-electrode.

5. The light valve type mask according to claim 1, wherein the number of the at least one first sub-electrode is one, the number of the at least one second sub-electrode is two, and the number of the at least one third sub-electrode is seven.

6. The light valve type mask according to claim 1, wherein the second electrode is a common electrode.

7. The light valve type mask according to claim 1, further comprising a first polarizing device and a second polarizing device, wherein the first polarizing device is disposed on an upper surface of the first substrate, and the second polarizing device is disposed on a lower surface of the second substrate.

8. A light valve type mask, comprising:
a first substrate;
a second substrate disposed opposite to the first substrate;
a first electrode disposed on a lower surface of the first substrate, the first electrode comprising at least one first sub-electrode having transmissivity, at least one second sub-electrode having transmissivity, and at least one third sub-electrode having no transmissivity;
a second electrode disposed on an upper surface of the second substrate and disposed opposite to the first electrode; and
a light valve medium disposed between the first electrode and the second electrode.

9. The light valve type mask according to claim 8, wherein a voltage is applied to the at least one first sub-electrode and the at least one second sub-electrode to make the at least one first sub-electrode and the at least one second sub-electrode transmissive, and no voltage is applied to the at least one third sub-electrode to make the at least one third sub-electrode non-transmissive.

10. The light valve type mask according to claim 8, wherein the at least one third sub-electrode is disposed between the at least one first sub-electrode and the at least one second sub-electrode.

11. The light valve type mask according to claim 8, wherein a first pixel area formed by the at least one first sub-electrode is different from a second pixel area formed by the at least one second sub-electrode.

12. The light valve type mask according to claim 11, wherein the first pixel area formed by the at least one first sub-electrode is greater than the second pixel area formed by the at least one second sub-electrode.

13. The light valve type mask according to claim 12, wherein the first pixel area formed by the at least one first sub-electrode is twice the second pixel area formed by the at least one second sub-electrode.

14. The light valve type mask according to claim 8, wherein a size of the at least one first sub-electrode, a size of the at least one second sub-electrode, and a size of the at least one third sub-electrode are same.

15. The light valve type mask according to claim 8, wherein the number of the at least one first sub-electrode is one, the number of the at least one second sub-electrode is two, and the number of the at least one third sub-electrode is seven.

16. The light valve type mask according to claim 8, wherein the second electrode is a common electrode.

17. The light valve type mask according to claim 8, further comprising a first polarizing device and a second polarizing device, wherein the first polarizing device is disposed on an upper surface of the first substrate, and the second polarizing device is disposed on a lower surface of the second substrate.
